(19) United States
(12) Patent Application Publication
(10) Pub. No.: US 2025/0212496 A1
(43) Pub. Date: Jun. 26, 2025

(54) ISOLATION FORMATION METHOD IN HIGH-ASPECT RATIO CMOS STACKED DEVICES

(71) Applicant: Applied Materials, Inc., Santa Clara, CA (US)

(72) Inventors: Sai Hooi YEONG, San Jose, CA (US); Gregory COSTRINI, Flanders, NJ (US); Ashish PAL, San Ramon, CA (US); El Mehdi BAZIZI, San Jose, CA (US)

(73) Assignee: Applied Materials, Inc., Santa Clara, CA (US)

(21) Appl. No.: 18/394,352

(22) Filed: Dec. 22, 2023

(51) Int. Cl. H01L 21/8238; H01L 27/092; H01L 29/06; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/115; H10D 62/121; H10D 64/017; H10D 84/0167; H10D 84/0172; H10D 84/0188; H10D 84/856

(57) ABSTRACT

A system and method for forming an isolator in a complementary field effect transistor (CFET) is disclosed. In one aspect the method includes: fabricating a plurality of CFET devices, each device including a first metal-oxide-semiconductor (MOS) device and a second MOS device, wherein the first MOS device and the second MOS device are complementary; removing a filler between the first MOS device and the second MOS device of a first CFET device; depositing a dielectric material between the first CFET device and a second CFET device to fill a void between the first MOS device and the second MOS device of the first CFET device; etching the dielectric material; repeating the depositing and etching steps to fill the void between the first MOS device and the second MOS device of the first CFET device; and performing a final etching to remove the dielectric material between the first and second CFET.

### TECHNICAL FIELD

The present disclosure relates generally to quasi-planar architecture logic devices and specifically to forming isolation between complementary metal-oxide-semiconductor in a gate all around (GAA) structure.

### BACKGROUND

The current generation of advanced logic devices are quasi-planar architecture Gate All Around (GAA) devices that have evolved from Fin-Field-Effect-Transistor (FinFET) technology. GAA devices enable area scaling in several ways by essentially stacking a fin of channels vertically in a form of nanosheets. This enables better gate control in increasingly smaller devices, device performance and, in addition, reduces the footprint of the GAA device relative to a FinFET device.

The next generation of device architecture beyond GAA is to stack GAA devices vertically, which is referred to as Complementary FET or CFET architecture. There are many process-related challenges to build such devices, some of which are related to isolating stacked NMOS and PMOS devices.

The insulating feature is fabricated after the poly-gate feature is formed. As a result, this feature, referred to as the “NP Dielectric Isolation” or NPDI, must be filled with dielectric insulator material (e.g., SiO2, SiN, SiON, SiOCN, SiCN, SiBCN) in the high-aspect canyon (e.g., average range of between 20 to 50 nm) formed between the poly-gates.

One difficulty is that current process methods will fill the gate canyon before the cavity is filled. In addition, the NP dielectric isolation fill is highly desired to be void/seam-free to avoid potential downstream wet processes, thus impacting the wafer die yield. The process requirement for NPDI fill is beyond current-generation advanced-node process technology.

It would therefore be advantageous to provide a solution that would overcome the challenges noted above.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

In one general aspect, method may include fabricating a plurality of CFET devices, each CFET device including a first metal-oxide-semiconductor (MOS) device and a second MOS device, where the first MOS device and the second MOS device are complementary devices. Method may also include removing a filler material between the first MOS device and the second MOS device of a first CFET device. Method may furthermore include depositing a dielectric material between the first CFET device and a second CFET device to fill a void between the first MOS device and the second MOS device of the first CFET device. Method may in addition include etching the dielectric material. Method may moreover include repeating the depositing and etching steps to fill the void between the first MOS device and the second MOS device of the first CFET device. Method may also include performing a final etching to remove the dielectric material between the first CFET and the second CFET. Other embodiments of this aspect include corresponding computer systems, apparatus, and computer programs recorded on one or more computer storage devices, each configured to perform the actions of the methods.

Implementations may include one or more of the following features. Method may include: determining a number of times to repeat the depositing and etching steps. Method where the determined number is further determined based on any one of: a CFET architecture, a size of the void, an area of the void, a volume of the void, a dimension of the void, a type of material used as NPDI filler, and any combination thereof. Method where removing the filler further comprises: etching away the filler material. Implementations of the described techniques may include hardware, a method or process, or a computer tangible medium.

In one general aspect, method may include fabricating a plurality of CFET devices, each CFET device including a first metal-oxide-semiconductor (MOS) device and a second MOS device, where the first MOS device and the second MOS device are complementary devices. Method may also include removing a filler material between the first MOS device and the second MOS device of a first CFET device, where the CFET device includes a first sidewall between the first CFET device and a second CFET device, and a second sidewall between the first CFET device and a third CFET device. Method may furthermore include poisoning the first sidewall and the second sidewall to inhibit dielectric adhesion. Method may in addition include depositing a dielectric material between the first CFET device and the second CFET device to fill a void between the first MOS device and the second MOS device of the first CFET device. Other embodiments of this aspect include corresponding computer systems, apparatus, and computer programs recorded on one or more computer storage devices, each configured to perform the actions of the methods.

Implementations may include one or more of the following features. Method where poisoning the first sidewall and the second sidewall further comprises: depositing an inhibitor agent on the first sidewall; and depositing the inhibitor agent on the second sidewall. Method may include: determining a number of times to repeat the depositing and etching steps. Method where the determined number is further determined based on any one of: a CFET architecture, a size of the void, an area of the void, a volume of the void, a dimension of the void, a type of material used as NPDI filler, and any combination thereof. Method where removing the filler further comprises: etching away the filler material. Method where removing the filler further comprises: etching away the filler material. Implementations of the described techniques may include hardware, a method or process, or a computer tangible medium.

In one general aspect, method may include fabricating a plurality of CFET devices, each CFET device including a first metal-oxide-semiconductor (MOS) device and a second MOS device, where the first MOS device and the second MOS device are complementary devices. Method may also include removing a filler material between the first MOS device and the second MOS device of a first CFET device, where the CFET device includes a first sidewall between the first CFET device and a second CFET device, and a second sidewall between the first CFET device and a third CFET device. Method may furthermore include depositing selectively a dielectric material between the first CFET device and the second CFET device only on a predefined region, to fill a void between the first MOS device and the second MOS device of the first CFET device. Other embodiments of this aspect include corresponding computer systems, apparatus, and computer programs recorded on one or more computer storage devices, each configured to perform the actions of the methods.

Implementations may include one or more of the following features. Method may include: poisoning the first sidewall and the second sidewall to inhibit dielectric adhesion. Method where poisoning the first sidewall and the second sidewall further comprises: depositing an inhibitor agent on the first sidewall; and depositing the inhibitor agent on the second sidewall. Method where the selective deposition is determined based on any one of: a CFET architecture, a size of the void, an area of the void, a volume of the void, a dimension of the void, a type of material used as NPDI filler, and any combination thereof. Implementations of the described techniques may include hardware, a method or process, or a computer tangible medium.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1A is an example isometric view of a complementary field effect transistor (CFET), implemented in accordance with an embodiment.

FIG. 1B is an example isometric view of a CFET after S/D etching, implemented in accordance with an embodiment.

FIG. 2 is an example isometric view of a CFET after NPDI removal.

FIG. 3 is an example isometric view of a CFET with a chemical vapor deposition (CVD) of dielectric fill, utilized to describe an embodiment.

FIG. 4A is an example isometric view of a CFET illustrating a pinched off canyon utilizing a chemical vapor deposition of dielectric fill, utilized to describe an embodiment.

FIG. 4B is an example isometric view of a CFET illustrating a pinched off canyon utilizing a chemical vapor deposition of dielectric fill, utilized to describe another embodiment.

FIG. 4C is an example isometric view of a CFET illustrating a pinched off canyon utilizing a chemical vapor deposition of dielectric fill, utilized to describe yet another embodiment.

FIG. 4D is an example isometric view of a CFET illustrating a pinched off canyon utilizing an atomic layer deposition (ALD) of dielectric fill, utilized to describe an embodiment.

FIG. 5A is an example diagram showing a first portion of a flow of filling an NP void with dielectric utilizing atomic layer deposition, implemented in accordance with an embodiment.

FIG. 5B is an example diagram showing a second portion of a flow of filling an NP void with dielectric utilizing atomic layer deposition, implemented in accordance with an embodiment.

FIG. 5C is an example flowchart of a method for filling an NPDI void using a deposition etching technique, implemented in accordance with an embodiment.

FIG. 6A is an example schematic illustration of a fabrication flow for filing an NPDI void utilizing sidewall poisoning, implemented in accordance with an embodiment.

FIG. 6B is an example flowchart of a method for fabricating an NPDI dielectric in a CFET device, implemented in accordance with an embodiment.

FIG. 7A is an example schematic illustration of a fabrication flow for filing an NPDI void utilizing selective NPDI deposition, implemented in accordance with an embodiment.

FIG. 7B is an example flowchart of a method for performing selective NPDI deposition to fill an NPDI void, implemented according to an embodiment.

FIG. 8 is an example illustration of a multi-stack CFET device, implemented in accordance with an embodiment.

FIG. 9 is an example schematic diagram of a system according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

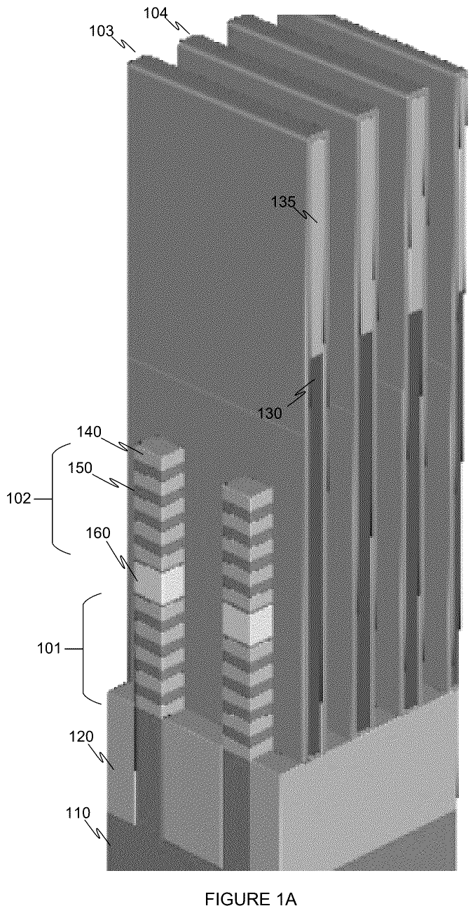

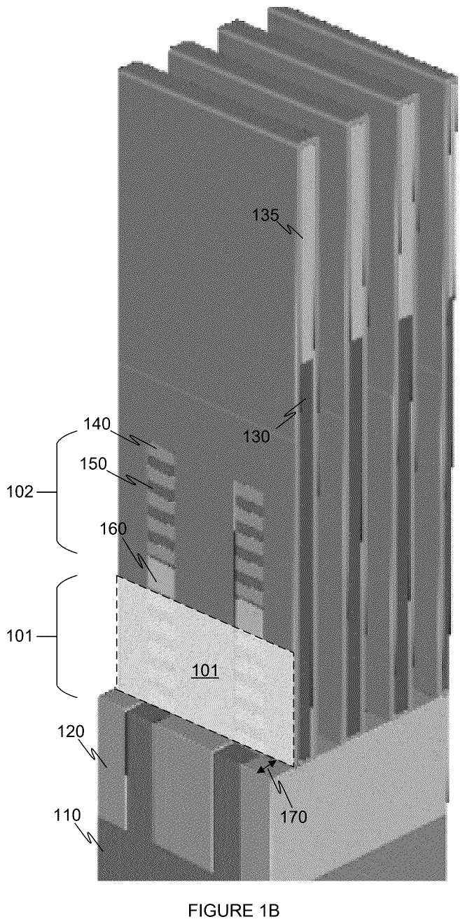

FIG. 1A is an example isometric view of a complementary field effect transistor (CFET), implemented in accordance with an embodiment. In an embodiment, a plurality of fins are formed over a stacked CMOS device. For example, a first fin 103 and a second fin 104 are formed.

In an embodiment, the first fin 103 is formed over a CMOS stack including a first MOS device 101 and a second MOS device 102, which is complementary to the first MOS device 101. In an embodiment, an NMOS is complementary to a PMOS and vice versa.

In an embodiment, the second MOS device 102 includes a plurality of channels, such as first channel 150, such that between each channel a metal layer 140 is deposited to form a gate-all-around (GAA) device.

Furthermore, an NP dielectric isolator (NPDI) 160 is formed between the stacked MOS devices (e.g., first MOS device 101 and second MOS device 102). For example, according to an embodiment, the first MOS device 101 is a PMOS device, the second MOS device 102 is an NMOS device, and the NPDI 160 is fabricated, for example from SiGe.

In an embodiment, each recess between a pair of fins, such as first fin 103 and second fin 104 is etched to isolate the fins from one another. This is referred to as source/drain (S/D) etching.

In some embodiments, a CFET includes a first MOS device 101 and a second MOS device 102. In an embodiment, the CFET further includes a dummy poly gate 130, and a hard mask 135.

FIG. 1B is an example isometric view of a CFET after S/D etching, implemented in accordance with an embodiment. In an embodiment, an S/D channel connecting a plurality of fins is etched away between the fins, so as to create a gap distance 170 between each fin. In an embodiment, etching is performed to remove the epitaxy layers of the CFET, such as first channel 150 and metal layer 140.

In an embodiment, once S/D etching is complete, the NPDI filler 160 is removed. In some embodiments, the NPDI filler 160 is removed and replaced with an NPDI dielectric material, such as SiO2, SiN, SiON, SIOCN, SiCN, SiBCN.

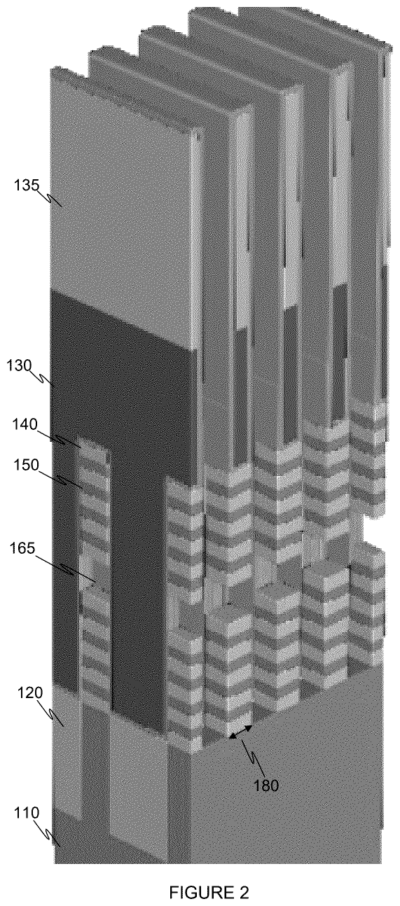

FIG. 2 is an example isometric view of a CFET after NPDI removal. In an embodiment, removing the NPDI filler 160 results in an NPDI void 165. It is desirable to fill the NPDI void 165. The CFET with an NPDI void 165 is a baseline for the following figures and explanations of the following embodiments.

In some embodiments, the NPDI void 165 has a width 180, which is equal to, or less than the width of a fin. In an embodiment, filling the NPDI void 165 needs to be performed prior to filling the canyon between the fins (e.g., defined by the gap 170). In certain embodiments, a CFET fin has a height of between 20 to 50 nanometers (nm).

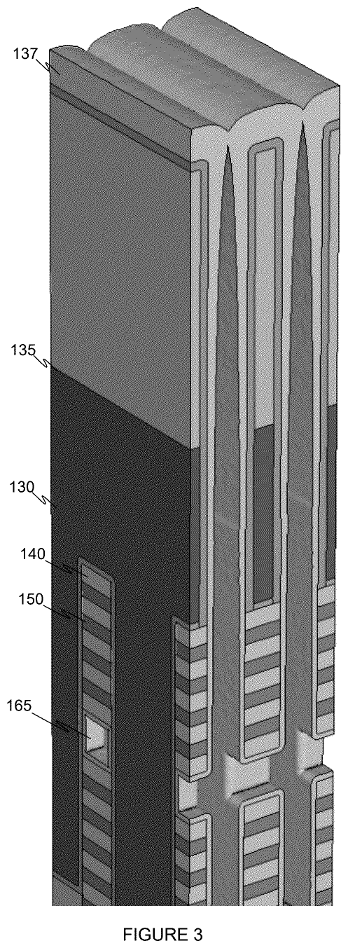

FIG. 3 is an example isometric view of a CFET with a chemical vapor deposition (CVD) of dielectric fill, utilized to describe an embodiment. In an embodiment, a dielectric fill 137 is deposited using a chemical vapor deposition (CVD) process. In certain embodiments, due to the narrow gap between the fins, the canyon is filled before the NPDI void 165 is completely filled. This results in an unfilled canyon in some embodiments, or in ‘seams’ (i.e., voids) according to other embodiments, in the NPDI which are not desirable.

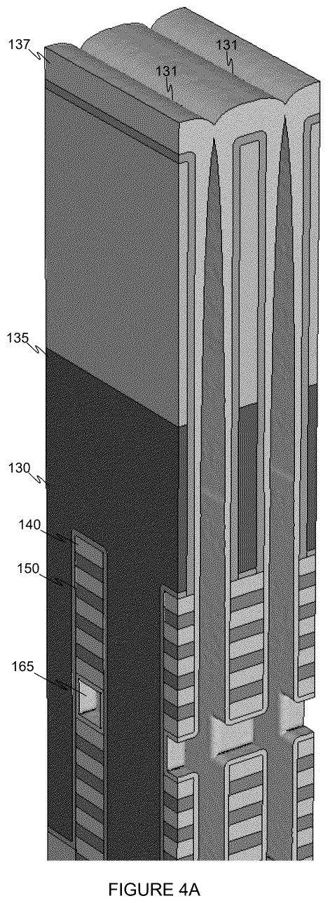

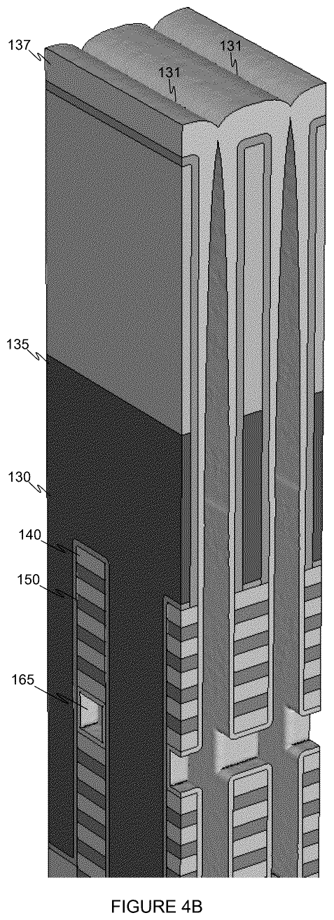

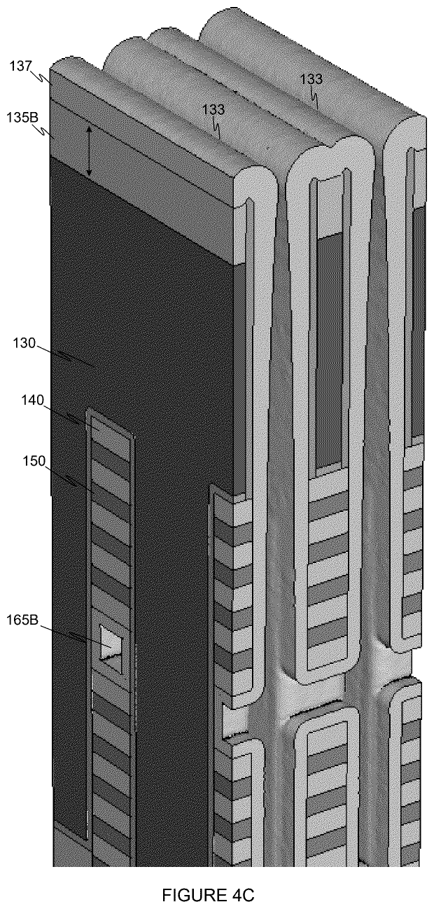

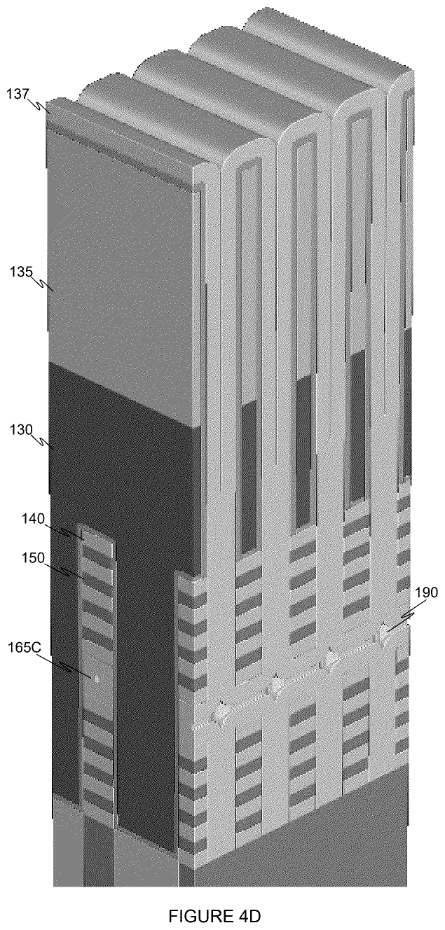

FIG. 4A is an example isometric view of a CFET illustrating a pinched off canyon utilizing a chemical vapor deposition of dielectric fill, utilized to describe an embodiment. As detailed above, it is not desirable to form such a dielectric fill.

In an embodiment, a pinched off canyon 131 is a result of performing a chemical vapor deposition. According to an embodiment, as the chemical vapor deposition is performed from the top down, the deposition tends to stick to the sidewalls of the fin (i.e., the sides of the canyon), thus pinching off the gap before the canyon is filled.

FIG. 4B is an example isometric view of a CFET illustrating a pinched off canyon utilizing a chemical vapor deposition of dielectric fill, utilized to describe another embodiment.

In an embodiment, a lower sticking coefficient is utilized, however this still results in a pinched off dielectric fill 132. In some embodiments, this results in a dielectric fill with a deeper pinch (valley) between the fins.

FIG. 4C is an example isometric view of a CFET illustrating a pinched off canyon utilizing a chemical vapor deposition of dielectric fill, utilized to describe yet another embodiment.

In an embodiment, a lower sticking coefficient is utilized, together with a hard mask 135B having a thinner cross section than of the hard mask 135 of FIG. 4B, for example. According to an embodiment, the dielectric fill still results in a pinched effect, for example at a valley 133. In some embodiments, this dielectric fill deposition results in in a valley formed on top of the fins, as well as a valley 133 between the fins. In some embodiments, the valley 133 between the fins is not fully closed.

In some embodiments, utilizing this method allows to increase the dielectric fill in the void 165B, relative to, for example, the void 165 of FIG. 4B.

FIG. 4D is an example isometric view of a CFET illustrating a pinched off canyon utilizing an atomic layer deposition (ALD) of dielectric fill, utilized to describe an embodiment.

According to an embodiment, an ALD process includes utilizing one or more reactants, such that each reactant is deposited individually in a sequential manner. In certain embodiments, performing an ALD process for the NPDI dielectric fill allows to increase filling the void 165C, however this still results in an incomplete fill.

Additionally, in some embodiments, a void 190 is present in the canyon between fins when utilizing an ALD process. Therefore, the method still falls short of the target, which is to fill the void without leaving voids or seams.

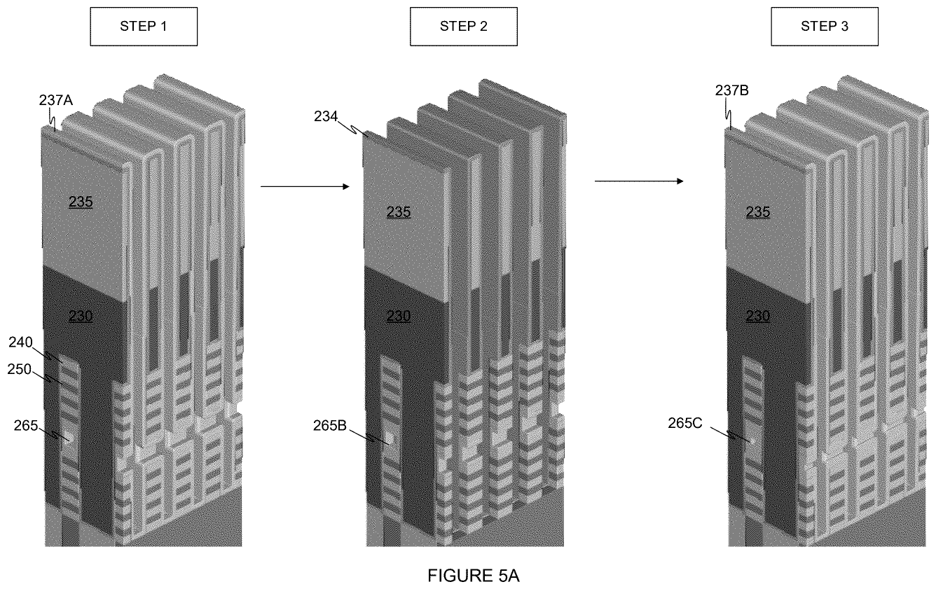

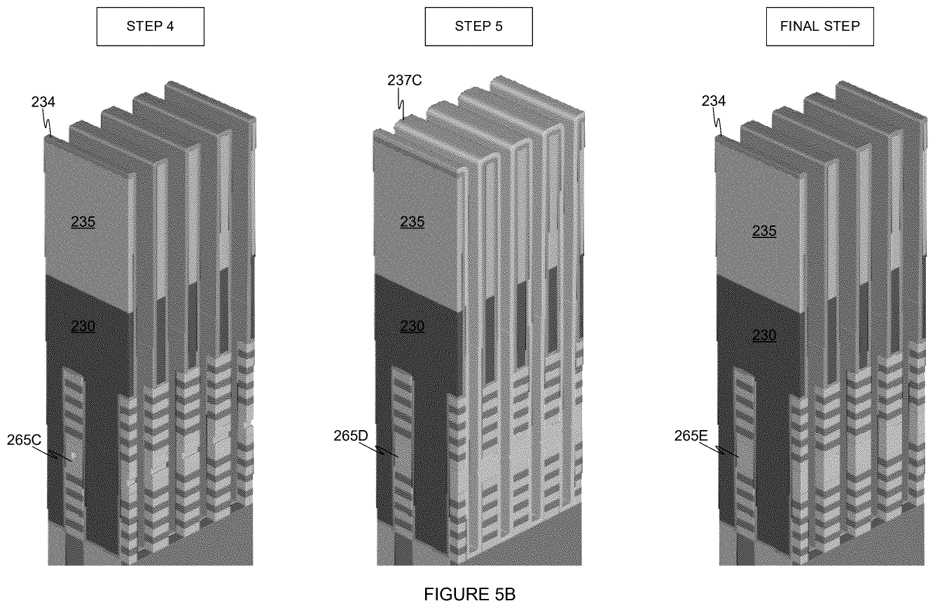

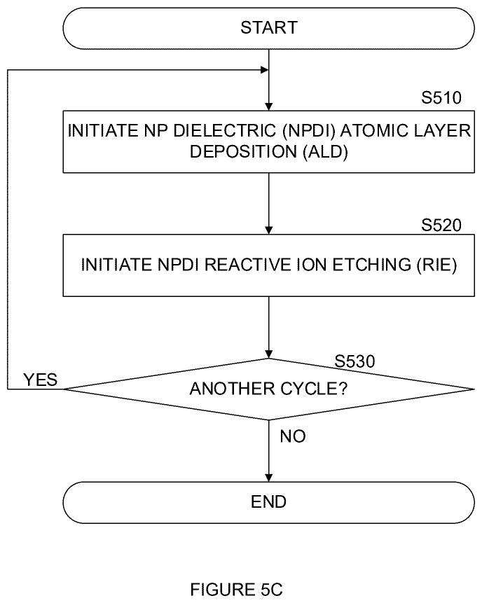

FIG. 5A is an example diagram showing a first portion of a flow of filling an NP void with dielectric utilizing atomic layer deposition, implemented in accordance with an embodiment. FIG. 5B is an example diagram showing a second portion of a flow of filling an NP void with dielectric utilizing atomic layer deposition, implemented in accordance with an embodiment.

In an embodiment, a CFET includes a first MOS and a second MOS, each having an epitaxy layer, each epitaxy including a plurality of channels, such as channel 250 and a plurality of metal layers such as metal layer 240. In an embodiment, a gate 230 is deposited on, and to the sides of, the epitaxy layers. In certain embodiments, a hard mask 235 is deposited on top of the gate 230. In some embodiments, a spacer filler 234 is deposited after the hard mask 235.

In certain embodiments, a filler is utilized between the first MOS and the second MOS, which when removed forms an NP void 265, i.e., a void separating an NMOS FET from a PMOS FET.

In an embodiment, at a first step, an NPDI dielectric 237A is deposited, for example via atomic layer deposition. In some embodiments, the NPDI dielectric 237A is a layer having a thickness of 5 nm. In an embodiment, after step 1 is complete, the void 265 is partially filled, resulting in a partially filled void 265B.

In some embodiments, at a second step, the NPDI dielectric 237A is removed, for example via reactive ion etching (RIE), deep RIE, and the like. In an embodiment, reactive ion etching is a dry etching process, which reduces mask undercut, which is a phenomena that occurs in some wet etching processes. In an embodiment, a chemically reactive plasma is utilized under low pressure conditions to remove a material deposited on a wafer. In an embodiment, a directional electromagnetic field is generated in a chamber in which the wafer is present, which results in initiation of plasma.

According to an embodiment, at a third step, another NPDI dielectric 237B layer is deposited. In an embodiment, the NPDI dielectric 237B is deposited utilizing atomic layer deposition. For example, in some embodiments, the NPI dielectric 237B has a layer thickness of 5 nm. This results, according to an embodiment, of an additional filling on the NPDI void 265B, such that an NPDI void 265C includes more NPDI dielectric material than the NPDI void 265B of the previous step.

In certain embodiments, this process is repeated, for example based on an area size of the NPDI void, based on a volume size of the NPDI void, based on a dimension of the NPDI void, and the like. For example, in an embodiment, the number of repetitions (e.g., depositing NPDI dielectric and etching the NPDI dielectric) is proportional to the height of the NPDI void.

At a fourth step reactive ion etching is utilized to remove the NPDI dielectric, according to an embodiment. In an embodiment, the RIE process is utilized for a period of time which removes NPDI dielectric material in the canyon between fins, without removing fill from the NPDI void.

In an embodiment, at a fifth step, a third NPDI dielectric 237C layer is deposited. In certain embodiments, deposition of the third NPDI dielectric 237C layer results in a filling of the NPDI void 265C to the NPDI void 265D, such that the NPDI void 265D includes more dielectric material within a volume of the NPDI void than the NPDI void 265C.

In some embodiments, at a final step, the NPDI void 265E is completely filled with NPDI dielectric, and reactive ion etching is utilized to remove the NPDI dielectric filler material between the CFETs (i.e., between the fins).

FIG. 5C is an example flowchart of a method for filling an NPDI void using a deposition etching technique, implemented in accordance with an embodiment. In an embodiment, the flowchart is utilized to describe the filling of the NPDI void as discussed in more detail with respect to FIGS. 5A and 5B above.

At S510, an NP dielectric (NPDI) layer is deposited. In an embodiment, the NPDI layer is deposited using an atomic layer deposition technique. In some embodiments, an atomic layer deposition includes sequential use of a gas-phase chemical process. In an embodiment, a first reactant and a second reactant are utilized, by depositing only the first reactant, allowing the first reactant to fully interact with a surface material, then depositing the second reactant, allowing the second reactant to fully interact. This cycle is repeated to deposit a layer of material on top of a substrate.

In an embodiment, NPDI layer is approximately 5 nm thick. In some embodiments, the NPDI dielectric material is SiO2, SiN, SiON, SiOCN, SiCN, SiBCN, and the like. According to an embodiment, the NPDI material is deposited between a first epitaxy layer of a first MOS device, and a second epitaxy layer of a second MOS device.

At S520, the NPDI material is removed. In an embodiment, removing the NPDI material is performed utilizing a reactive ion etching technique. In certain embodiments, reactive ion etching allows removing material without creating an undercut under as masked area, such as may occur when using a wet etching technique.

In certain embodiments, the NPDI material that is removed is material which is present in the ‘canyons’, which are the voids between CFET fins. In some embodiments, removal of the NPDI material does not result in removal of NPDI material from the NPDI void between the FETs of a single CFET.

At S530, a check is performed if another cycle should be initiated. In some embodiments, a number of cycles is predetermined, for example based on the CFET architecture, a size of the void between epitaxy layers of each FET of a single CFET, an area of the void, a volume of the void, a dimension of the void, the type of material used as NPDI filler, a combination thereof, and the like.

In some embodiments, where the check results in ‘yes’, execution continues at S510. In other embodiments, where the check results in ‘no’, execution terminates. In an embodiment, once execution terminates, additional fabrication techniques are utilized to fabricate layers, deposit material, remove material, etc.

In certain embodiments, performing this process results in an NPDI void that is filled with insulator material resulting in no void, and seam free. This is advantageous to avoid potential downstream wet processes, this impacting the wafer die yield.

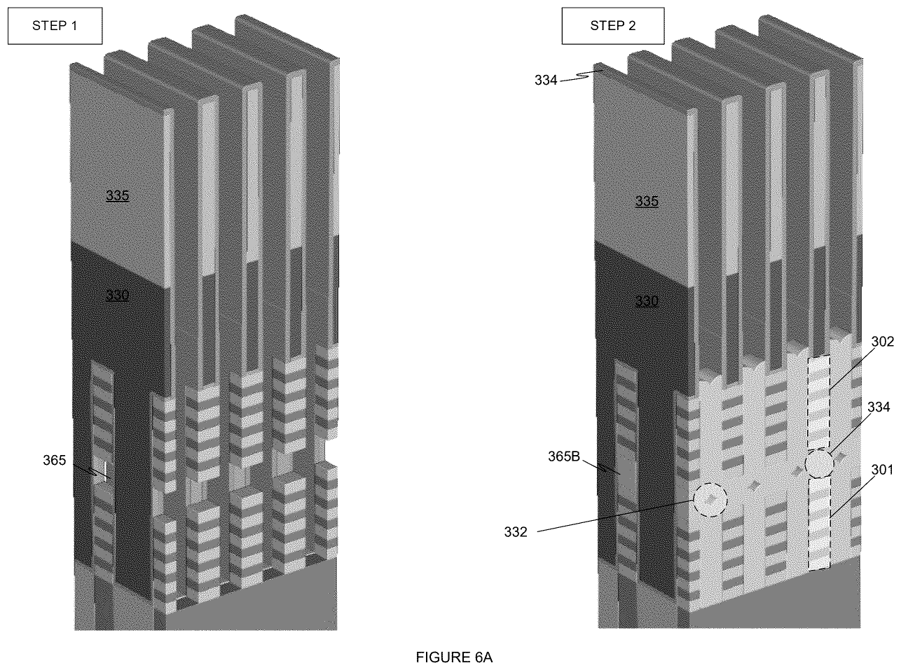

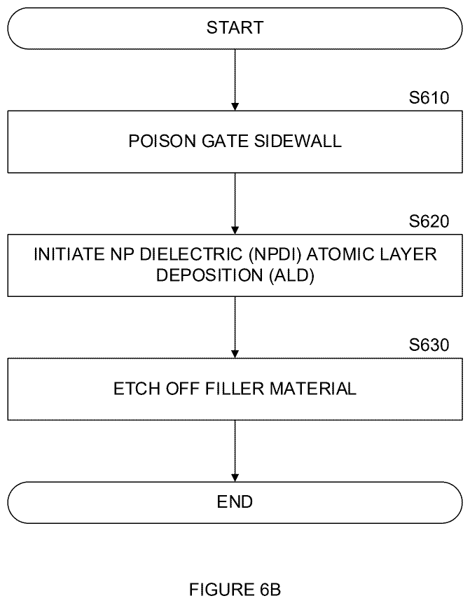

FIG. 6A is an example schematic illustration of a fabrication flow for filing an NPDI void utilizing sidewall poisoning, implemented in accordance with an embodiment. In certain embodiments, a first step of a fabrication process includes removal of SiGe resulting in an NPDI void 365, which needs to be filled with a dielectric material.

According to an embodiment, the sidewalls are poisoned, for example by depositing an agent which inhibits growth or attachment to the sidewalls.

In some embodiments, the NPDI void 365 is filled utilizing an atomic layer deposition fabrication process, for example of 14 nm thickness. In an embodiment, this fills the NPDI void 365B with dielectric material. In some embodiments, a void 332 occurs between sidewalls, while a filler 334 is fully present in between the top epitaxy layer 301 and the bottom epitaxy layer 302.

According to an embodiment, the NPDI dielectric material is removed at a subsequent etch step. In an embodiment, the NPD void 365 is therefore filled in a single step, reducing the total number of steps required to fabricate the NPDI dielectric, thereby increasing process simplicity.

In this embodiment, the deposition of the NPDI dielectric proceeds on the exposed device features and in the cavity between the devices. More specifically, the void in the deposited dielectric shows that a path to transport the dielectric into the cavity. This indicates that it is possible, according to an embodiment, to fill the NPDI cavity 365 in one deposition step. A subsequent etch step is required to remove the deposition in the gate canyon space between devices.

FIG. 6B is an example flowchart of a method for fabricating an NPDI dielectric in a CFET device, implemented in accordance with an embodiment.

At S610, a gate sidewall is poisoned. In an embodiment, a CFET device includes a top epitaxy layer and a bottom epitaxy layer. In some embodiments, the top epitaxy layer and the bottom epitaxy layer are separated by a SiGe layer. In certain embodiments, the SiGe layer is removed prior to poisoning the gate sidewalls. Removal of the SiGe layer is required in order to deposit a dielectric in the NPDI void between the epitaxy layers of a CFET device.

In certain embodiments, poisoning a gate sidewall includes depositing an agent that inhibits, prevents, and the like, growth, attachment, etc. to the sidewalls.

At S620, an atomic layer deposition is initiated. In an embodiment, initiating an atomic layer deposition includes utilizing an ALD process to deposit an NP dielectric material in a canyon defined between a first CFET device and a second CFET device. In some embodiments, the NP dielectric material is SiO2, SiN, SiON, SiOCN, SiCN, SiBCN, a combination thereof, and the like.

In some embodiments, the ALD layer thickness is approximately 14 nm thick. In certain embodiments, the ALD layer thickness is determined based on a determined height of the gate sidewalls. In an embodiment, the ALD layer thickness is further determined based on a distance between a first CFET device and a second CFET device (i.e., the width of the canyon).

At S630, the NPDI material is removed. In an embodiment, removing the NPDI material is performed utilizing a reactive ion etching technique. In certain embodiments, reactive ion etching allows removing material without creating an undercut under as masked area, such as may occur when using a wet etching technique.

In certain embodiments, the NPDI material that is removed is material which is present in the ‘canyons’, which are the voids between CFET fins. In some embodiments, removal of the NPDI material does not result in removal of NPDI material from the NPDI void between the FETs of a single CFET.

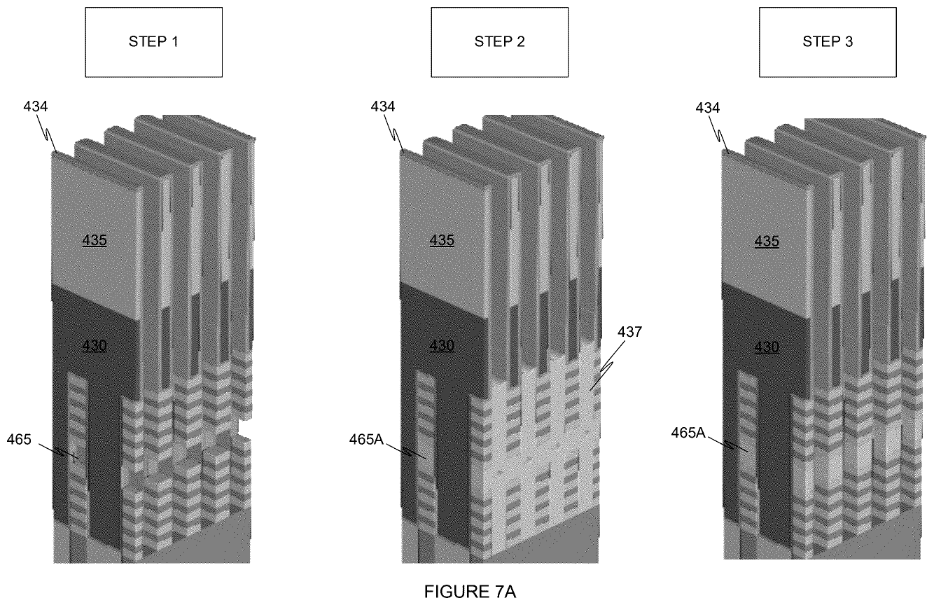

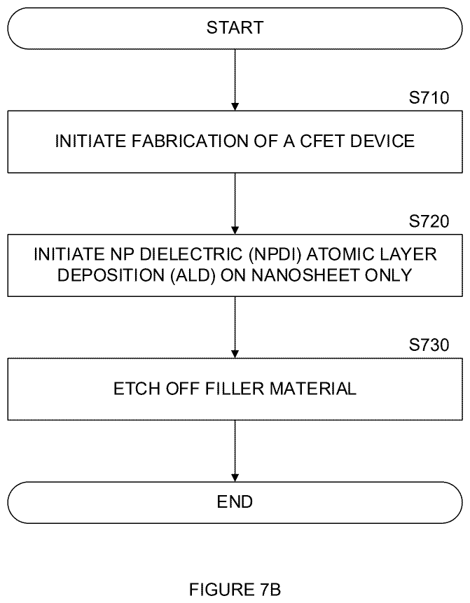

FIG. 7A is an example schematic illustration of a fabrication flow for filing an NPDI void utilizing selective NPDI deposition, implemented in accordance with an embodiment. In certain embodiments, a first step of a fabrication process includes removal of SiGe resulting in an NPDI void 365, which needs to be filled with a dielectric material. For example, in an embodiment, the first step incudes a CFET device including a top epitaxy layer and a bottom epitaxy layer with an NPDI void 465 in between, and a gate 430 fabricated all around. In an embodiment, a hard mask 435 is positioned on top of the gate 430. A spacer filler 434 is deposited on top of the hard mask 435.

At step 2, an atomic layer deposition process is utilized to deposit an NPDI dielectric. In some embodiments, the deposition is a selective deposition, such that the NPDI dielectric is deposited on only Si and SiGe. In an embodiment, selective deposition is achieved by

In an embodiment, as with the process described above in FIGS. 6A and 6B, at Step 2 the NPDI void is full of NPDI dielectric material 465A, and filler material 437 is present in a canyon between the CFET devices.

At step 3, the NPDI dielectric material is removed at a subsequent etch step. In an embodiment, the NPD void 465 is therefore filled in a single step, reducing the total number of steps required to fabricate the NPDI dielectric, thereby increasing process simplicity. This process is advantageous, in an embodiment, as it reduces the requirement of poisoning the gate sidewalls in order to avoid adhesion of the NPDI dielectric during deposition.

FIG. 7B is an example flowchart of a method for performing selective NPDI deposition to fill an NPDI void, implemented according to an embodiment.

At S710, a CFET device fabrication is initiated. In an embodiment, a CFET device includes a top epitaxy layer and a bottom epitaxy layer. In some embodiments, the top epitaxy layer and the bottom epitaxy layer are separated by a SiGe layer. In certain embodiments, the SiGe layer is removed, so that a dielectric can be deposited in the NPDI void between the epitaxy layers of a CFET device.

At S720, a selective atomic layer deposition is initiated. In an embodiment, initiating an atomic layer deposition includes utilizing an ALD process to deposit an NP dielectric material only on Si and SiGe areas of the CFET device. In an embodiment, a canyon is defined between a first CFET device and a second CFET device. In some embodiments, the NP dielectric material is SiO2, SiN, SiON, SiOCN, SiCN, SiBCN, a combination thereof, and the like. In an embodiment, a build-up of NP dielectric material occurs, resulting in filler material present in the canyon between the CFET devices.

In some embodiments, the ALD layer thickness is approximately 14 nm thick. In certain embodiments, the ALD layer thickness is determined based on a determined height of the gate sidewalls. In an embodiment, the ALD layer thickness is further determined based on a distance between a first CFET device and a second CFET device (i.e., the width of the canyon).

At S730, the NPDI material is removed. In an embodiment, removing the NPDI material is performed utilizing a reactive ion etching technique. In certain embodiments, reactive ion etching allows removing material without creating an undercut under as masked area, such as may occur when using a wet etching technique.

In certain embodiments, the NPDI material that is removed is material which is present in the ‘canyons’, which are the voids between CFET fins. In some embodiments, removal of the NPDI material does not result in removal of NPDI material from the NPDI void between the FETs of a single CFET.

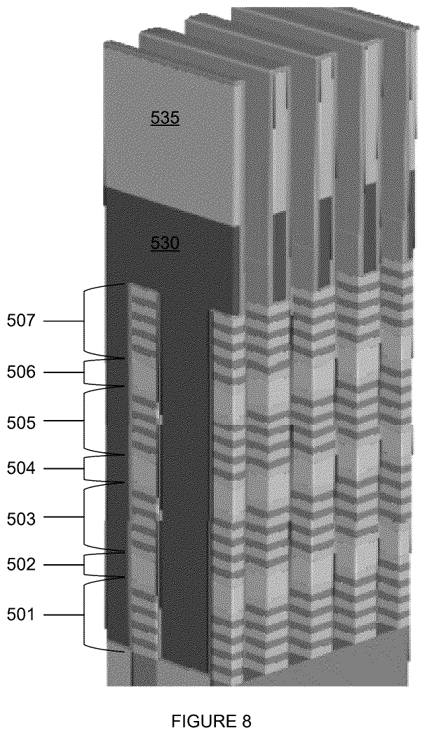

FIG. 8 is an example illustration of a multi-stack CFET device, implemented in accordance with an embodiment. While this illustrative embodiment includes four epitaxy layers, it is understood that utilizing this technology to separate epitaxy layers with dielectric filler in the NP void, can be utilized in other embodiments to further increase the number of stacked devices.

In an embodiment, a multi-stack CFET device includes a plurality of epitaxy layers, such as bottom epitaxy layer 501, first epitaxy layer 503, second epitaxy layer 505, and top epitaxy layer 507. In some embodiments, the bottom epitaxy layer 501 is separated from the first epitaxy layer 503 by a first NPDI dielectric fill 502. In certain embodiments, the first epitaxy layer 501 is separated from the second epitaxy layer 505 by a second NPDI dielectric fill 504. According to an embodiment, the second epitaxy layer 505 and the top epitaxy layer 507 are separated by a third NPDI dielectric fill 506.

In certain embodiments, the bottom epitaxy layer 501 is an NMOS device, the first epitaxy layer 503 is a PMOS device, the second epitaxy layer 505 is an NMOS device, and the top epitaxy layer 507 is a PMOS device. In this arrangement, the first epitaxy layer 502 is complementary with the bottom epitaxy layer 501 and the second epitaxy layer 505. In an embodiment, the second epitaxy layer 505 is complementary with the top epitaxy layer 507 and the first epitaxy layer 503.

In some embodiments, the bottom epitaxy layer 501 is a PMOS device, the first epitaxy layer 503 is an NMOS device, the second epitaxy layer 505 is a PMOS device, and the top epitaxy layer 507 is an NMOS device. In this arrangement, the first epitaxy layer 502 is complementary with the bottom epitaxy layer 501 and the second epitaxy layer 505. In an embodiment, the second epitaxy layer 505 is complementary with the top epitaxy layer 507 and the first epitaxy layer 503.

According to an embodiment, a gate layer 530 is deposited all around the stacked epitaxy layers. A hard mask 535 is deposited on the gate layer 530, in certain embodiments.

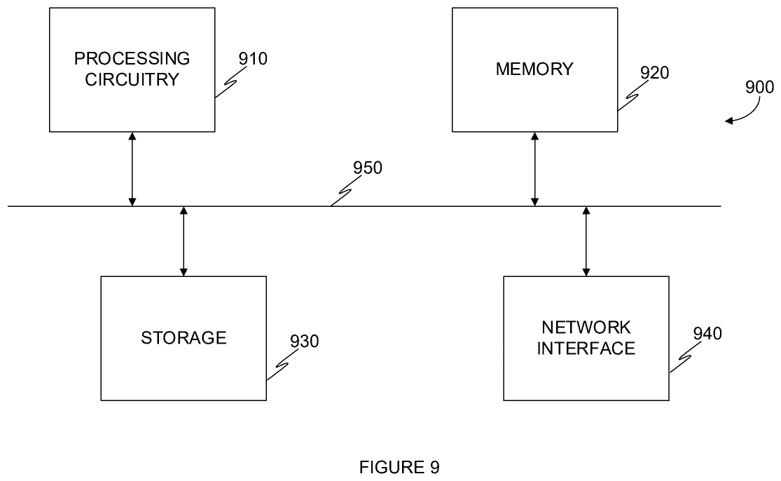

FIG. 9 is an example schematic diagram of a system 900 according to an embodiment. The system 900 includes a processing circuitry 910 coupled to a memory 920, a storage 930, and a network interface 940. In an embodiment, the components of the system 130 may be communicatively connected via a bus 950.

The processing circuitry 910 may be realized as one or more hardware logic components and circuits. For example, and without limitation, illustrative types of hardware logic components that can be used include field programmable gate arrays (FPGAs), application-specific integrated circuits (ASICs), Application-specific standard products (ASSPs), system-on-a-chip systems (SOCs), graphics processing units (GPUs), tensor processing units (TPUs), general-purpose microprocessors, microcontrollers, digital signal processors (DSPs), and the like, or any other hardware logic components that can perform calculations or other manipulations of information.

The memory 920 may be volatile (e.g., random access memory, etc.), non-volatile (e.g., read only memory, flash memory, etc.), or a combination thereof. In an embodiment, the memory 920 is an on-chip memory, an off-chip memory, a combination thereof, and the like. In certain embodiments, the memory 920 is a scratch-pad memory for the processing circuitry 910.

In one configuration, software for implementing one or more embodiments disclosed herein may be stored in the storage 930, in the memory 920, in a combination thereof, and the like. Software shall be construed broadly to mean any type of instructions, whether referred to as software, firmware, middleware, microcode, hardware description language, or otherwise. Instructions may include code (e.g., in source code format, binary code format, executable code format, or any other suitable format of code). The instructions, when executed by the processing circuitry 910, cause the processing circuitry 910 to perform the various processes described herein.

The storage 930 is a magnetic storage, an optical storage, a solid-state storage, a combination thereof, and the like, and is realized, according to an embodiment, as a flash memory, as a hard-disk drive, or other memory technology, or any other medium which can be used to store the desired information.

The network interface 940 is configured to provide the system 900 with communication with, for example, a semiconductor fabrication system, configured to perform the methods discussed in more detail herein.

It should be understood that the embodiments described herein are not limited to the specific architecture illustrated in FIG. 9, and other architectures may be equally used without departing from the scope of the disclosed embodiments.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art, and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for forming an isolator in a complementary field effect transistor (CFET), comprising:
fabricating a plurality of CFET devices, each CFET device including a first metal-oxide-semiconductor (MOS) device and a second MOS device, wherein the first MOS device and the second MOS device are complementary devices;
removing a filler material between the first MOS device and the second MOS device of a first CFET device;
depositing a dielectric material between the first CFET device and a second CFET device to fill a void between the first MOS device and the second MOS device of the first CFET device;
etching the dielectric material;
repeating the depositing and etching steps to fill the void between the first MOS device and the second MOS device of the first CFET device; and
performing a final etching to remove the dielectric material between the first CFET and the second CFET.

2. The method of claim 1, further comprising:
determining a number of times to repeat the depositing and etching steps.

3. The method of claim 2, wherein the determined number is further determined based on any one of: a CFET architecture, a size of the void, an area of the void, a volume of the void, a dimension of the void, a type of material used as NPDI filler, and any combination thereof.

4. The method of claim 1, wherein removing the filler further comprises:
etching away the filler material.

5. A method for forming an isolator in a complementary field effect transistor (CFET), comprising:
fabricating a plurality of CFET devices, each CFET device including a first metal-oxide-semiconductor (MOS) device and a second MOS device, wherein the first MOS device and the second MOS device are complementary devices;
removing a filler material between the first MOS device and the second MOS device of a first CFET device, wherein the CFET device includes a first sidewall between the first CFET device and a second CFET device, and a second sidewall between the first CFET device and a third CFET device;
poisoning the first sidewall and the second sidewall to inhibit dielectric adhesion; and
depositing a dielectric material between the first CFET device and the second CFET device to fill a void between the first MOS device and the second MOS device of the first CFET device.

6. The method of claim 5, wherein poisoning the first sidewall and the second sidewall further comprises:
depositing an inhibitor agent on the first sidewall; and
depositing the inhibitor agent on the second sidewall.

7. The method of claim 5, further comprising:
determining a number of times to repeat the depositing and etching steps.

8. The method of claim 7, wherein the determined number is further determined based on any one of: a CFET architecture, a size of the void, an area of the void, a volume of the void, a dimension of the void, a type of material used as NPDI filler, and any combination thereof.

9. The method of claim 5, wherein removing the filler further comprises:
etching away the filler material.

10. A method for forming an isolator in a complementary field effect transistor (CFET), comprising:
fabricating a plurality of CFET devices, each CFET device including a first metal-oxide-semiconductor (MOS) device and a second MOS device, wherein the first MOS device and the second MOS device are complementary devices;
removing a filler material between the first MOS device and the second MOS device of a first CFET device, wherein the CFET device includes a first sidewall between the first CFET device and a second CFET device, and a second sidewall between the first CFET device and a third CFET device; and
depositing selectively a dielectric material between the first CFET device and the second CFET device only on a predefined region, to fill a void between the first MOS device and the second MOS device of the first CFET device.

11. The method of claim 10, further comprising:
poisoning the first sidewall and the second sidewall to inhibit dielectric adhesion.

12. The method of claim 11, wherein poisoning the first sidewall and the second sidewall further comprises:
depositing an inhibitor agent on the first sidewall; and
depositing the inhibitor agent on the second sidewall.

13. The method of claim 10, wherein the selective deposition is determined based on any one of: a CFET architecture, a size of the void, an area of the void, a volume of the void, a dimension of the void, a type of material used as NPDI filler, and any combination thereof.

14. The method of claim 5, wherein removing the filler further comprises:
etching away the filler material.
